(19) United States
(12) Patent Application Publication
(10) Pub. No.: US 2022/0146934 A1
(43) Pub. Date: May 12, 2022

(54) PHOTOSENSITIVE FIBER-FORMING COMPOSITION AND METHOD FOR FORMING FIBER PATTERN

(71) Applicants: TOYAMA PREFECTURE, Toyama-shi, Toyama (JP); NISSAN CHEMICAL CORPORATION, Tokyo (JP)

(72) Inventors: Yoshiyuki YOKOYAMA, Toyama-shi (JP); Takahiro KISHIOKA, Toyama-shi (JP)

(73) Assignees: TOYAMA PREFECTURE, Toyama-shi, Toyama (JP); NISSAN CHEMICAL CORPORATION, Tokyo (JP)

(21) Appl. No.: 17/429,489

(22) PCT Filed: Jan. 16, 2020
(86) PCT No.: PCT/JP2020/001296

§ 371 Date: Aug. 9, 2021

(30) Foreign Application Priority Data
Feb. 8, 2019 (JP) 2019-021730

(51) Int. Cl. G03F 7/039; G03F 7/09; D01F 6/36; D01F 6/34; G03F 7/20; H05K 3/02

(52) U.S. Cl. CPC G03F 7/039; G03F 7/09; H05K 3/027; D01F 6/34; G03F 7/20; D01F 6/36

(57) ABSTRACT

A method for producing a metal pattern by processing a substrate having on its surface a metal layer with a photosensitive fiber having a specific composition, a method for producing a metal pattern, and a composition for producing the photosensitive fiber. The photosensitive fiber contains a positive photosensitive material. The positive photosensitive material may contain a novolac resin, etc. The method for producing a metal pattern includes a first step of forming a fiber layer of photosensitive resin on a substrate having on its surface a metal layer; a second step of exposing the fiber layer to light via a mask; a third step of developing the fiber layer with a developer to thereby form a photosensitive fiber pattern; and a fourth step of etching the metal layer with an etchant and removing the photosensitive fiber, to thereby form a network metal pattern.

### TECHNICAL FIELD

The present invention relates to a photosensitive fiber-forming composition and a method for forming a fiber pattern. For example, a substrate having a metal pattern can be produced by coating a substrate having on its surface a metal layer with a photosensitive fiber containing a photosensitive material, and then etching the metal with the photosensitive fiber serving as a mask.

### BACKGROUND ART

In recent years, the market for transparent electrically conductive films and transparent wiring patterns using ITO (indium tin oxide) films has expanded in association with the growing demand for solar batteries and touch panels. However, indium, which is a rare metal, is expensive and fragile and has little bending resistance, and thus a strong demand has arisen for the development of alternative materials.

Recent development of electrospinning has led to the use of polymer nanofiber in a variety of fields including clothing, batteries, and medical treatment. Under such circumstances, studies have been conducted on new methods for forming a transparent electrically conductive film having a metal network structure finer than the wavelength of visible light by etching a metal thin film with a fine network structure of polymer nanofiber as an etching mask (Non-Patent Documents 1 and 2).

Patent Documents 1 and 2 describe a technique for imparting photosensitivity to a polymer nanofiber obtained by electrospinning and patterning a deposited nanofiber sheet into any shape with light (photosensitive nanofiber-forming technique).

### PRIOR ART DOCUMENTS

### Patent Documents

Patent Document 1: International Publication WO 2015/056789 pamphlet
Patent Document 2: International Publication WO 2016/171233 pamphlet Non-Patent Documents
Non-Patent Document 1: Keisuke Azuma, Koichi Sakajiri, Hidetoshi Matsumoto, Sungmin Kang, Junji Watanabe and Masatoshi Tokita, Mat. Lett., 115, 187 (2014)
Non-Patent Document 2: Tianda He, Aozhen Xie, Darrell H. Reneker and Yu Zhu, ACS Nano, 8 (5), 4782 (2014)

### SUMMARY OF THE INVENTION

### Problems to be Solved by the Invention

An object of the present invention for solving the aforementioned problems is to provide a method for producing a metal pattern by processing a substrate having on its surface a metal layer with a photosensitive fiber having a specific composition, a method for producing a metal pattern, and a composition for producing the photosensitive fiber.

One specific object for solving the aforementioned problems is to provide an inexpensive and flexible transparent wiring pattern and a film having a transparent wiring pattern in place of an ITO film by using a photosensitive nanofiber for a transparent electrically conductive film.

### Means for Solving the Problems

The present inventors have found that a wiring pattern having a fine metal network structure and exhibiting both bending resistance and electrical conductivity can be formed through a process in which a nanofiber formed from a photosensitive polymer having a specific composition by electrospinning is deposited onto a metal thin film that is vapor-deposited on a film, the photosensitive fiber is irradiated with light via a photomask to thereby pattern the fiber into a wiring form, and then the metal thin film is etched by using the photosensitive fiber as an etching mask. The present invention has been accomplished on the basis of this finding.

Accordingly, the present invention provides the following.

1. A photosensitive fiber formed of a positive photosensitive material, wherein the positive photosensitive material comprises a (meth)acrylic resin or a polyvinyl phenol resin and a dissolution inhibitor.

2. A composition for producing a photosensitive fiber, the composition comprising a (meth)acrylic resin or a polyvinyl phenol resin, a dissolution inhibitor, and a solvent.

3. The composition according to 2 above, wherein the composition further comprises an electrolyte.

4. A method for producing a photosensitive fiber, the method comprising a step of spinning the composition according to 2 or 3 above.

5. A method for producing a photosensitive fiber pattern, the method comprising a first step of spinning the composition according to 2 or 3 above to thereby form a fiber layer of photosensitive fiber on a substrate; a second step of exposing the fiber layer to light via a mask; and a third step of developing the fiber layer with a developer to thereby form a photosensitive fiber pattern.

6. A method for producing a metal pattern, the method comprising a first step of forming a fiber layer of photosensitive fiber on a substrate having on its surface a metal layer; a second step of exposing the fiber layer to light via a mask; a third step of developing the fiber layer with a developer to thereby form a photosensitive fiber pattern; and a fourth step of etching the metal layer with an etchant and removing the photosensitive fiber, to thereby form a network metal pattern.

7. The method for producing a metal pattern according to 6 above, wherein the photosensitive fiber contains (i) a novolac resin and a dissolution inhibitor; or (ii) a polyvinyl phenol resin or a (meth)acrylic resin and a photoacid generator; or (iii) a polyvinyl phenol resin or a (meth)acrylic resin including a structural unit having a photoacid generating group on a side chain; or (iv) a polyvinyl phenol resin or a (meth)acrylic resin and a dissolution inhibitor.

8. The method for producing a metal pattern according to 6 or 7 above, wherein the network metal pattern exhibits a light transmittance of 5% or more in a wavelength region of visible light.

9. The method for producing a metal pattern according to any one of 6 to 8 above, wherein the metal pattern can maintain electrical conductivity after 10 or more times of bending in a repeated bending test.

10. A method for producing a substrate having a metal pattern, the method comprising a first step of forming a fiber layer of photosensitive fiber on a substrate having on its surface a metal layer; a second step of exposing the fiber layer to light via a mask; a third step of developing the fiber layer with a developer to thereby form a photosensitive fiber pattern; and a fourth step of etching the metal layer with an etchant and removing the photosensitive fiber, to thereby form a network metal pattern.

11. The method for producing a substrate having a metal pattern according to 10 above, wherein the photosensitive fiber contains (i) a novolac resin and a dissolution inhibitor; or (ii) a polyvinyl phenol resin or a (meth)acrylic resin and a photoacid generator; or (iii) a polyvinyl phenol resin or a (meth)acrylic resin including a structural unit having a photoacid generating group on a side chain; or (iv) a polyvinyl phenol resin or a (meth)acrylic resin and a dissolution inhibitor.

12. A substrate having a metal pattern produced by the method for producing a substrate having a metal pattern according to 10 or 11 above.

13. The substrate having a metal pattern according to 12 above, wherein the network metal pattern exhibits a light transmittance of 5% or more in a wavelength region of visible light.

14. The substrate having a metal pattern according to 12 or 13 above, wherein the substrate having a metal pattern can maintain electrical conductivity after ten or more times of bending in a repeated bending test.

### Effects of the Invention

The present invention can provide a photosensitive fiber that can readily form a complicated and fine resist pattern, a fiber pattern formed from the photosensitive fiber, and production methods therefor.

The present invention can also provide a composition for producing the aforementioned photosensitive fiber (photosensitive fiber-forming composition).

The present invention can also provide a metal pattern formed from the aforementioned fiber pattern, a substrate having a metal pattern, and production methods therefor.

### BRIEF DESCRIPTION OF THE DRAWINGS

FIG. 1 is a schematic view showing a method for forming a transparent wiring pattern using a photosensitive fiber.

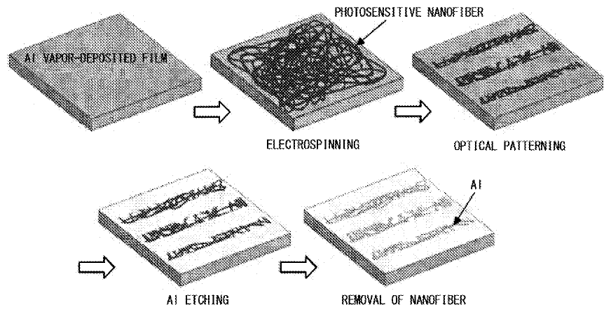

### MODES FOR CARRYING OUT THE INVENTION

1. Photosensitive Fiber and Production Method Therefor

The fiber of the present invention is mainly characterized by containing a positive photosensitive material. Thus, the fiber of the present invention is preferably a fiber prepared through spinning (more preferably electrospinning) of a raw material composition containing at least a positive photosensitive material.

In the present invention, the fiber containing a positive photosensitive material may be referred to as “positive photosensitive fiber.”

No particular limitation is imposed on the diameter of the fiber of the present invention, and the diameter can be appropriately adjusted depending on, for example, the intended use of the fiber. However, from the viewpoint of applying the fiber to, for example, an etching mask used for processing of any substrate used in a display or a semiconductor, a medical material, or a cosmetic material, the fiber of the present invention is preferably a fiber having a diameter on the order of nanometers (e.g., 1 to 1,000 nm) (i.e., nanofiber) and/or a fiber having a diameter on the order of micrometers (e.g., 1 to 1,000 μm) (i.e., microfiber). In the present invention, the diameter of the fiber is measured with a scanning electron microscope (SEM).

As used herein, the term “positive photosensitive material” refers to a material that undergoes a change in alkali solubility (from low or no alkali solubility to high alkali solubility) by the action of light (e.g., a positive photoresist or a positive photosensitive resin composition).

No particular limitation is imposed on the positive photosensitive material, so long as it can be formed into a fiber. The positive photosensitive material may be any known material that has conventionally been used as, for example, a positive photoresist or a positive photosensitive resin composition. Examples of the positive photosensitive material include (i) a novolac resin and a dissolution inhibitor; (ii) a polyvinyl phenol resin or a (meth)acrylic resin and a photoacid generator; and (iii) a polyvinyl phenol resin or a (meth)acrylic resin including a structural unit having a photoacid generating group on a side chain.

Alternatively, the positive photosensitive material used as, for example, a positive photosensitive resin composition may be (iv) a polyvinyl phenol resin or a (meth)acrylic resin and a dissolution inhibitor.

The positive photosensitive material used in the present invention may contain the aforementioned (i), the aforementioned (ii), the aforementioned (iii), or the aforementioned (iv).

No particular limitation is imposed on the usable novolac resin, so long as it has conventionally been used in a positive photosensitive material. The novolac resin is, for example, a resin prepared through polymerization of a phenol compound and an aldehyde compound in the presence of an acid catalyst.

Examples of the aforementioned phenol compound include phenol; cresol compounds, such as o-cresol, m-cresol, and p-cresol; xylenol compounds, such as 2,3-xylenol, 2,4-xylenol, 2,5-xylenol, 2,6-xylenol, 3,4-xylenol, and 3,5-xylenol; alkylphenol compounds, such as o-ethylphenol, m-ethylphenol, p-ethylphenol, 2-isopropylphenol, 3-isopropylphenol, 4-isopropylphenol, o-butylphenol, m-butylphenol, p-butylphenol, and p-tert-butylphenol; trialkylphenol compounds, such as 2,3,5-trimethylphenol and 3,4,5-trimethylphenol; polyhydric phenol compounds, such as resorcinol, catechol, hydroquinone, hydroquinone monomethyl ether, pyrogallol, and phloroglucinol; alkyl polyhydric phenol compounds, such as alkylresorcin, alkyl catechol, and alkylhydroquinone (any alkyl group has a carbon atom number of 1 to 4); α-naphthol; β-naphthol; hydroxydiphenyl; and bisphenol A. These phenol compounds may be used alone or in combination of two or more species.

Examples of the aforementioned aldehyde compound include formaldehyde, paraformaldehyde, furfural, benzaldehyde, nitrobenzaldehyde, and acetaldehyde. These aldehyde compounds may be used alone or in combination of two or more species.

Examples of the aforementioned acid catalyst include inorganic acids, such as hydrochloric acid, sulfuric acid, nitric acid, phosphoric acid, and phosphorus acid; organic acids, such as formic acid, oxalic acid, acetic acid, diethylsulfuric acid, and p-toluenesulfonic acid; and metal salts, such as zinc acetate.

No particular limitation is imposed on the weight average molecular weight of the novolac resin, but the weight average molecular weight is preferably 500 to 50,000. From the viewpoints of resolution and spinnability, the weight average molecular weight is more preferably 1,500 to 15,000.

As used herein, the term “weight average molecular weight” refers to the molecular weight in terms of polystyrene as measured by gel permeation chromatography (GPC).

No particular limitation is imposed on the usable dissolution inhibitor, so long as it has conventionally been used as a photosensitizer in a positive photosensitive material. Examples of the dissolution inhibitor include naphthoquinone diazide compounds, such as 1,2-naphthoquinone diazide-5-sufonate ester and 1,2-naphthoquinone diazide-4-sufonate ester. Preferably, 1,2-naphthoquinone diazide-5-sufonate ester is used.

The amount of the dissolution inhibitor is generally 5 to 50 parts by weight, preferably 10 to 40 parts by weight, relative to 100 parts by weight of the novolac resin.

No particular limitation is imposed on the usable polyvinyl phenol resin, so long as it has conventionally been used in a positive photosensitive material. The polyvinyl phenol resin is, for example, a resin prepared through polymerization of a hydroxystyrene compound in the presence of a radical polymerization initiator.

Examples of the aforementioned hydroxystyrene compound include o-hydroxy styrene, m-hydroxy styrene, p-hydroxystyrene, 2-(o-hydroxyphenyl)propylene, 2-(m-hydroxyphenyl)propylene, and 2-(p-hydroxyphenyl)propylene. These hydroxystyrene compounds may be used alone or in combination of two or more species.

Examples of the aforementioned radical polymerization initiator include organic peroxides, such as benzoyl peroxide, dicumyl peroxide, and dibutyl peroxide; and azobis compounds, such as azobisisobutyronitrile and azobisvaleronitrile.

No particular limitation is imposed on the weight average molecular weight of the polyvinyl phenol resin, but the weight average molecular weight is preferably 500 to 50,000. From the viewpoints of resolution and spinnability, the weight average molecular weight is more preferably 1,500 to 25,000.

No particular limitation is imposed on the usable (meth)acrylic resin, so long as it has conventionally been used in a positive photosensitive material. The (meth)acrylic resin is, for example, a resin prepared through polymerization of a polymerizable monomer having a (meth)acrylic group in the presence of a radical polymerization initiator.

Examples of the polymerizable monomer having a (meth)acrylic group include alkyl (meth)acrylate esters, such as methyl (meth)acrylate ester, ethyl (meth)acrylate ester, propyl (meth)acrylate ester, butyl (meth)acrylate ester, pentyl (meth)acrylate ester, hexyl (meth)acrylate ester, heptyl (meth)acrylate ester, octyl (meth)acrylate ester, 2-ethylhexyl (meth)acrylate ester, nonyl (meth)acrylate ester, decyl (meth)acrylate ester, undecyl (meth)acrylate ester, dodecyl (meth)acrylate ester, trifluoroethyl (meth)acrylate ester, and tetrafluoropropyl (meth)acrylate ester; acrylamides, such as diacetone acrylamide; and tetrahydrofurfuryl (meth)acrylate ester, dialkylaminoethyl (meth)acrylate ester, glycidyl (meth)acrylate ester, (meth)acrylic acid, α-bromo(meth)acrylic acid, α-chloro(meth)acrylic acid, β-furyl(meth)acrylic acid, and β-styryl(meth)acrylic acid. These polymerizable monomers having a (meth)acrylic group may be used alone or in combination of two or more species.

Examples of the aforementioned radical polymerization initiator include organic peroxides, such as benzoyl peroxide, dicumyl peroxide, and dibutyl peroxide; and azobis compounds, such as azobisisobutyronitrile and azobisvaleronitrile.

The aforementioned (meth)acrylic resin may be prepared through copolymerization of a polymerizable monomer having a (meth)acrylic group with one or more of polymerizable monomers, for example, polymerizable styrene derivatives having a substituent at a-position or the aromatic ring, such as styrene, vinyltoluene, and a-methylstyrene; acrylonitrile; vinyl alcohol esters, such as vinyl-n-butyl ether; maleic acid; maleic anhydride; maleic acid monoesters, such as monomethyl maleate, monoethyl maleate, and monoisopropyl maleate; fumaric acid; cinnamic acid; a-cyanocinnamic acid; itaconic acid; and crotonic acid.

As used herein, the term “(meth)acrylic” refers to both “acrylic” and “methacrylic.”

No particular limitation is imposed on the weight average molecular weight of the (meth)acrylic resin, but the weight average molecular weight is preferably 500 to 500,000. From the viewpoints of resolution and spinnability, the weight average molecular weight is more preferably 1,500 to 100,000.

The polyvinyl phenol resin or the (meth)acrylic resin preferably includes a structural unit having on its side chain an alkali-soluble group protected with an acid-unstable protective group.

Examples of the aforementioned acid-unstable protective group include tert-butyl group, tert-butoxycarbonyl group, tert-butoxycarbonylmethyl group, tert-amyloxycarbonyl group, tert-amyloxycarbonylmethyl group, 1,1-diethylpropyloxycarbonyl group, 1,1-diethylpropyloxycarbonylmethyl group, 1-ethylcyclopentyloxycarbonyl group, 1-ethylcyclopentyloxycarbonylmethyl group, 1-ethyl-2-cyclopentenyloxycarbonyl group, 1-ethyl-2-cyclopentenyloxycarbonylmethyl group, 1-ethoxyethoxycarbonylmethyl group, 2-tetrahydropyranyloxycarbonylmethyl group, 2-tetrahydrofuranyloxycarbonylmethyl group, tetrahydrofuran-2-yl group, 2-methyltetrahydrofuran-2-yl group, tetrahydropyran-2-yl group, and 2-methyltetrahydropyran-2-yl group.

Examples of the aforementioned alkali-soluble group include phenolic hydroxy group and carboxy group.

The polyvinyl phenol resin or the (meth)acrylic resin including a structural unit having on its side chain an alkali-soluble group protected with an acid-unstable protective group can be produced by, for example, introducing an acid-unstable protective group through chemical reaction into an alkali-soluble group of the polyvinyl phenol resin or the (meth)acrylic resin. Alternatively, the polyvinyl phenol resin or the (meth)acrylic resin including a structural unit having on its side chain an alkali-soluble group protected with an acid-unstable protective group can be produced by mixing a raw material monomer of the polyvinyl phenol resin or the (meth)acrylic resin with a monomer corresponding to the structural unit having on its side chain an alkali-soluble group protected with an acid-unstable protective group, and copolymerizing the resultant monomer mixture.

No particular limitation is imposed on the photoacid generator, so long as it is a compound that generates an acid directly or indirectly by the action of light. Examples of the photoacid generator include a diazomethane compound, an onium salt compound, a sulfonimide compound, a nitrobenzyl compound, an iron-arene complex, a benzoin tosylate compound, a halogen-containing triazine compound, a cyano-group-containing oxime sulfonate compound, and a naphthalimide compound.

The amount of the photoacid generator is generally 0.1 to 50 parts by weight, preferably 3 to 30 parts by weight, relative to 100 parts by weight of the polyvinyl phenol resin or the (meth)acrylic resin.

The polyvinyl phenol resin or the (meth)acrylic resin including a structural unit having on its side chain a photoacid generating group can be produced by, for example, mixing a raw material monomer of the polyvinyl phenol resin or the (meth)acrylic resin with any of the aforementioned photoacid generators as a monomer, and copolymerizing the resultant monomer mixture.

No particular limitation is imposed on the weight average molecular weight of the polyvinyl phenol resin including a structural unit having on its side chain a photoacid generating group, but the weight average molecular weight is preferably 500 to 50,000. From the viewpoints of resolution and spinnability, the weight average molecular weight is more preferably 1,500 to 25,000.

No particular limitation is imposed on the weight average molecular weight of the (meth)acrylic resin including a structural unit having on its side chain a photoacid generating group, but the weight average molecular weight is preferably 500 to 500,000. From the viewpoints of resolution and spinnability, the weight average molecular weight is more preferably 1,500 to 10,000.

The positive photosensitive material can be produced by any method known per se. For example, the positive photosensitive material (positive photoresist) containing (i) a novolac resin and a dissolution inhibitor can be produced by the method described in, for example, Japanese Examined Patent Publication No. 1995-66184; the positive photosensitive material (positive photoresist) containing (ii) a polyvinyl phenol resin or an acrylic resin and a photoacid generator can be produced by the method described in, for example, Japanese Examined Patent Publication No. 1995-66184, or Japanese Unexamined Patent Application Publication No. 2007-79589 or No. 1998-207066; and the positive photosensitive material (positive photoresist) containing (iii) a polyvinyl phenol resin or acrylic resin including a structural unit having on its side chain a photoacid generating group can be produced by the method described in, for example, Japanese Unexamined Patent Application Publication No. 1997-189998, No. 2002-72483, No. 2010-85971, or No. 2010-256856. Alternatively, the positive photosensitive material may be a commercially available product.

The positive photosensitive material (iv) can be produced by the method described in, for example, Japanese Patent No. 5093525.

The fiber of the present invention is suitably produced by spinning of a photosensitive fiber-producing composition containing the positive photosensitive material and a solvent.

No particular limitation is imposed on the solvent, so long as it can dissolve or disperse the positive photosensitive material homogeneously and dose not react with the respective materials. Preferably, a polar solvent is used.

Examples of the polar solvent include water, methanol, ethanol, 2-propanol, propylene glycol monomethyl ether, propylene glycol monomethyl ether acetate, acetone, dimethylformamide, dimethylacetamide, N-methylpyrrolidone, and hexafluoroisopropanol. From the viewpoint of ease of spinning of the photosensitive fiber-producing composition, the polar solvent is preferably propylene glycol monomethyl ether, propylene glycol monomethyl ether acetate, or hexafluoroisopropanol.

These solvents may be used alone or in combination of two or more species.

The fiber of the present invention is suitably produced by spinning of a photosensitive fiber-producing composition containing the positive photosensitive material, a solvent, and an electrolyte (hereinafter, the composition may be referred to simply as “the composition of the present invention”).

The electrolyte is, for example, tetrabutylammonium chloride.

The amount of the positive photosensitive material contained in the composition of the present invention is preferably 60 to 100% by weight, more preferably 60 to 95% by weight, particularly preferably 70 to 90% by weight, on the basis of the solid content (except for the solvent) of the photosensitive fiber-producing composition, from the viewpoints of resolution and spinnability.

The composition of the present invention may optionally contain, besides the positive photosensitive material, an additive that is generally used in a fiber-producing composition, so long as the object of the present invention is not considerably impaired. Examples of the additive include a surfactant, a rheology controlling agent, a chemical, and fine particles.

The composition of the present invention is prepared by mixing the positive photosensitive material with a solvent, or mixing the resultant mixture with any of the aforementioned additives. No particular limitation is imposed on the mixing method, and the mixing can be performed by any method known per se or a method similar thereto.

No particular limitation is imposed on the method for spinning the composition of the present invention, so long as the method can form a fiber. Examples of the method include melt blowing, combined melt spinning, and electrospinning. From the viewpoint of formability of ultrafine fiber (nanofiber or microfiber), electrospinning is preferably used.

Electrospinning is a known spinning method and can be performed with any known electrospinning apparatus. The conditions for electrospinning; for example, the rate of discharging the composition of the present invention from the tip end of a nozzle (e.g., needle) (i.e., discharge rate), applied voltage, and the distance between the tip end of the nozzle from which the composition of the present invention is discharged and a substrate that receives the composition (i.e., discharge distance), can be appropriately determined depending on, for example the diameter of a fiber to be produced. The discharge rate is generally 0.1 to 100 μL/min, preferably 0.5 to 50 μL/min, more preferably 1 to 20 μL/min. The applied voltage is generally 0.5 to 80 kV, preferably 1 to 60 kV, more preferably 3 to 40 kV. The discharge distance is generally 1 to 60 cm, preferably 2 to 40 cm, more preferably 3 to 30 cm.

Electrospinning may be performed with, for example, a drum collector. The use of a drum collector, etc. can control the orientation of the resultant fiber. For example, when the drum is rotated at a low speed, nonwoven fabric, etc. can be produced, whereas when the drum is rotated at a high speed, an oriented fiber sheet, etc. can be produced. This technique is effective for the production of, for example, an etching mask material used for processing of a semiconductor material (e.g., a substrate).

The fiber production method of the present invention may include, in addition to the aforementioned spinning step, a step of heating the spun fiber at a specific temperature. Since the applied fiber functions as a mask for an electrically conductive layer, the fiber must adhere to the electrically conductive layer. When this adhesion is insufficient, defects (e.g., disconnection) may occur in the resultant fiber network structure, resulting in poor electrical conductivity. An effective method for increasing the adhesion between the applied fiber and the electrically conductive layer is to, for example, heat the fiber at a temperature equal to or higher than the glass transition temperature of the fiber.

The temperature of heating the spun fiber is generally 70 to 300° C., preferably 80 to 250° C., more preferably 90 to 200° C.

No particular limitation is imposed on the method for heating the spun fiber, so long as the method can heat the fiber at the aforementioned heating temperature. The spun fiber can be appropriately heated by any method known per se or a method similar thereto. Specific examples of the heating method include a method involving the use of, for example, a hot plate or an oven in air.

The time of heating the spun fiber can be appropriately determined depending on, for example, the heating temperature. From the viewpoints of crosslinking reaction rate and production efficiency, the heating time is preferably one minute to 48 hours, more preferably five minutes to 36 hours, particularly preferably 10 minutes to 24 hours.

The fiber of the present invention has photosensitivity. Thus, the fiber can be used for the production of, for example, an etching mask material used for processing of a semiconductor material (e.g., a substrate), a medical material, or a cosmetic material. In particular, nanofiber or microfiber can be suitably used for the production of, for example, an etching mask having pores, or a cell culture substrate having a pattern (biomimetic substrate, for example, a substrate for co-culture with vascular cells, etc. for preventing deterioration of cultured cells).

2. Production Methods for Photosensitive Fiber Pattern and Substrate Having Photosensitive Fiber Pattern

The fiber of the present invention has photosensitivity; specifically, the fiber of the present invention is a positive photosensitive fiber. Thus, when the fiber is aggregated to form a fiber layer, and the fiber layer is directly subjected to lithographic treatment, an exposed portion of the fiber is removed through solubilization, and unexposed portion of the fiber remains, to thereby form a fiber pattern. The lithographic treatment of a fiber layer formed of nanofiber and/or microfiber can form a complicated and fine fiber pattern.

The fiber in the fiber layer is aggregated in a one-dimensional, two-dimensional, or three-dimensional state, and the aggregation state may or may not have regularity. The term “pattern” as used herein refers to one recognized as the shape of a spatial object (e.g., a design or a pattern) mainly formed of straight lines, curves, and a combination of these. The pattern itself may or may not have regularity, so long as the pattern has any shape.

The present invention provides a method for forming a photosensitive fiber pattern, the method including a first step of spinning the aforementioned photosensitive fiber-producing composition to thereby form a fiber layer of photosensitive fiber (preferably the fiber of the present invention) on a substrate; a second step of exposing the fiber layer to light via a mask; and a third step of developing the fiber layer with a developer to thereby form a photosensitive fiber pattern. The method may also be referred to as a production method for a fiber pattern. Alternatively, the method may be referred to as a production method for a substrate having a fiber pattern, since the method can produce a substrate having a fiber pattern.

[First Step]

The first step involves spinning the aforementioned photosensitive fiber-producing composition to thereby form a fiber layer of photosensitive fiber (preferably the fiber of the present invention) on a substrate.

No particular limitation is imposed on the method for forming a fiber layer of photosensitive fiber (preferably the fiber of the present invention) on a substrate. For example, the composition of the present invention may be spun directly on a substrate to thereby form a fiber layer.

No particular limitation is imposed on the substrate, so long as the substrate is formed of a material that does not deform or denature in lithographic treatment. The material of the substrate may be, for example, resin, glass, ceramic, plastic, a semiconductor material such as silicon, film, sheet, plate, fabric (woven fabric, knitted fabric, or nonwoven fabric), or yarn.

The resin serving as the material of the substrate may be a natural resin or a synthetic resin. The natural resin used is preferably, for example, cellulose, cellulose triacetate (CTA), or dextran sulfate-immobilized cellulose. The synthetic resin used is preferably, for example, polyacrylonitrile (PAN), polyester-based polymer alloy (PEPA), polystyrene (PS), polysulfone (PSF), polymethyl methacrylate (PMMA), polyvinyl alcohol (PVA), polyurethane (PU), ethylene vinyl alcohol (EVAL), polyethylene (PE), polyester (PE) (e.g., polyethylene terephthalate (PET)), polypropylene (PP), polyvinylidene fluoride (PVDF), any ion-exchange rein, or polyether sulfone (PES). In order to impart repeated bending property (bending resistance) as described below, polyester (PE) is preferred, and the polyester (PE) is particularly preferably polyethylene terephthalate (PET).

No particular limitation is imposed on the basis weight of the fiber in the fiber layer after formation of the pattern (amount of the fiber per unit area on the substrate). For example, the amount of the fiber may be such a level that a fiber layer having a thickness of about 5 μm to 50 μm is formed.

[Second Step]

The second step involves exposing the fiber formed on the substrate in the first step to light via a mask. The light exposure can be performed with, for example, g-rays (wavelength: 436 nm), h-rays (wavelength: 405 nm), i-rays (wavelength: 365 nm), a mercury lamp, any laser (e.g., excimer laser, such as KrF excimer laser (wavelength: 248 nm), ArF excimer laser (wavelength: 193 nm), or F2 excimer laser (wavelength: 157 nm)), EUV (extreme ultraviolet rays, wavelength: 13 nm), or LED.

After the light exposure of the photosensitive fiber, the fiber may optionally be heated; i.e., post exposure bake (PEB) may be performed. The heating temperature can be appropriately determined depending on, for example, the heating time, and is generally 80 to 200° C. The heating time can be appropriately determined depending on, for example, the heating temperature, and is generally one to 20 minutes.

[Third Step]

The third step involves developing the fiber exposed to light and optionally heated in the second step with a developer. The developer can be appropriately selected from developers that are generally used for forming a pattern from a photosensitive composition. More preferably, the developer used in the third step contains water or an organic solvent.

Water may be used alone or used in the form of an aqueous alkaline solution (e.g., an aqueous solution of an alkali, for example, an inorganic alkali, such as sodium hydroxide, potassium hydroxide, sodium carbonate, sodium silicate, sodium metasilicate, or aqueous ammonia; a primary amine, such as ethylamine or N-propylamine; a secondary amine, such as diethylamine or di-N-butylamine; a tertiary amine, such as triethylamine or methyldiethylamine; an alcohol amine, such as dimethylethanolamine or triethanolamine; a tertiary ammonium salt, such as tetramethylammonium hydroxide, tetraethylammonium hydroxide, or choline; or a cyclic amine, such as pyrrole or piperidine).

Examples of the organic solvent include alcohols (e.g., 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 2-methyl-2-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, 1-butoxy-2-propanol, and cyclohexanol), and solvents used in, for example, common resist compositions (e.g., ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate).

The developer used in the third step is preferably water, ethyl lactate, or an aqueous solution of tetramethylammonium hydroxide, particularly preferably water or ethyl lactate. The developer preferably has a near-neutral or basic pH. The developer may contain an additive such as a surfactant.

The photosensitive fiber pattern of the present invention formed on the substrate through the aforementioned steps is used along with the substrate, or used separately from the substrate.

In the case where the photosensitive fiber pattern of the present invention is used along with the substrate, the substrate (i.e., the substrate having on its surface the photosensitive fiber pattern of the present invention) can be suitably used as, for example, an etching mask used for processing of a substrate (e.g., semiconductor) or a cell culture scaffold material, when the photosensitive fiber pattern of the present invention is formed of nanofiber and/or microfiber. When the substrate having on its surface the photosensitive fiber pattern of the present invention is used as a cell culture scaffold material, the substrate is preferably formed of glass or plastic.

3. Production Methods for Metal Pattern and Substrate Having Metal Pattern

The present invention can provide a method for producing a metal pattern, the method including a first step of forming a fiber layer of photosensitive fiber (preferably the fiber of the present invention) on a substrate having on its surface a metal layer; a second step of exposing the fiber layer to light via a mask; a third step of developing the fiber layer with a developer to thereby form a photosensitive fiber pattern; and a fourth step of etching the metal layer with an etchant and removing the photosensitive fiber, to thereby form a metal pattern.

The first step of the metal pattern production method differs from the first step of the aforementioned photosensitive fiber pattern production method in that the substrate has on its surface a metal layer.

[First Step]

The first step involves forming a fiber layer of photosensitive fiber on a substrate having on its surface a metal layer.

Examples of the metal include metals such as cobalt, nickel, copper, zinc, chromium, molybdenum, ruthenium, rhodium, palladium, silver, cadmium, osmium, titanium, iridium, platinum, gold, and aluminum; and alloys of these metals. The metal of the metal pattern of the present invention is not limited to these examples, and any electrically conductive metal can be used. In order to provide a transparent electrically conductive film using the metal pattern of the present invention, copper, silver, or aluminum is preferably used from the viewpoint of electrical conductivity. In order to provide a flexible transparent electrode (transparent electrically conductive film), a metal such as aluminum or copper or an alloy thereof is preferably used, and aluminum is more preferably used from the viewpoint of lightweight and low cost.

[Second Step]

The second step involves exposing the fiber formed on the substrate having on its surface a metal layer in the first step to light via a mask.

The light used for exposure and the heating of the fiber after the light exposure in the second step can refer back to the description in the second step of the method mentioned above in the section “2.”

[Third Step]

The third step involves developing the fiber exposed to light and optionally heated in the second step with a developer.

The developer used in the third step can refer back to the description in the third step of the method mentioned above in the section “2.”

[Fourth Step]

The fourth step involves etching the metal layer corresponding to a fiber layer portion developed in the third step with an etchant, and removing the photosensitive fiber, to thereby form a metal pattern.

Regarding the etching, removal of the metal layer region uncoated with the fiber, which depends on the property of the metal forming the metal layer, is performed by, for example, a wet process in which the metal layer region is immersed in an aqueous solution of an acid (e.g., hydrochloric acid or nitric acid) or an aqueous solution of sodium hydroxide or potassium hydroxide, and the metal is formed into an ion or a complex ion, to thereby dissolve the metal layer in the aqueous solution. The immersion time, temperature, etc. can be appropriately determined depending on the type or concentration of the aforementioned aqueous solution and the type or thickness of the metal layer to be dissolved. The wet process may optionally be replaced with a dry process using an organic gas or a halogen gas.

After removal of the metal layer region uncoated with the photosensitive fiber, the substrate including the metal pattern coated with the photosensitive fiber is preferably washed with, for example, water thoroughly, in order to remove impurities, such as a compound generated through formation of the ion or complex ion from the metal, and the solute contained in the aqueous solution. Thereafter, the photosensitive fiber coating the metal pattern is removed. In general, the photosensitive fiber can be thoroughly removed with an organic solvent. For example, the photosensitive fiber can be removed with acetone.

This step can form, on the substrate, a metal pattern composed of a fine metal network structure; specifically, a network metal pattern, or a wiring pattern having a network metal pattern as a wiring.

After removal of the aforementioned photosensitive fiber, the network metal pattern exhibits a light transmittance of, for example, 5% or more, for example, 8% or more, for example, 10% or more, for example, 15% or more, for example, 20% or more, for example, 30% or more, for example, 40% or more, for example, 50% or more, for example, 60% or more in a wavelength region of visible light.

The metal pattern of the present invention formed on the substrate through the aforementioned steps is used along with the substrate, or used separately from the substrate. When the metal pattern is used along with the substrate, the substrate having the metal pattern is provided.

<Repeated Bending Property (Bending Resistance)>

The metal pattern of the present invention and the substrate having the metal pattern exhibit resistance to repeated bending. Specifically, as described in Examples below, the metal pattern undergoes a small change in sheet resistance even after, for example, two or more times, five or more times, 10 or more times, 50 or more times, 100 or more times, or 200 or more times of bending at a bend radius of 2 mm (for example, the rate of change in sheet resistance is 10% or less relative to that before the bending).

Examples of the relationship between light transmittance, sheet resistance, and fiber coating percentage include, but are not limited to, combinations described below.

When the aforementioned network metal pattern exhibits a light transmittance of 5 to 11% in a wavelength region of visible light, the sheet resistance is 5 to 9Ω/□, and the fiber coating percentage is 75% to 90%. When the aforementioned network metal pattern exhibits a light transmittance of 12% or more (for example, 15% or more, for example, 20% or more, for example, 30% or more, for example, 40% or more, for example, 50% or more, for example, 60% or more) in a wavelength region of visible light, the sheet resistance is 10 to 500Ω/□, and the fiber coating percentage is 1 to 70%.

### EXAMPLES

The present invention will next be described by way of Examples, but the present invention should not be construed as being limited to the following Examples.

[Measurement of Weight Average Molecular Weight]

In Examples, the weight average molecular weight of a polymer was measured by gel permeation chromatography (GPC). The following apparatus and conditions were used for the measurement.

Apparatus: TOSOH HLC-8320 GPC system

Column: Shodex (registered trademark) KF-803L, KF-802, and KF-801

Column temperature: 40° C.

Eluent: DMF

Flow rate: 0.6 mL/minute

Detector: RI

Standard sample: polystyrene

### Example 1

<a. Production of Copolymer>

Firstly, 10 g of benzyl acrylate and 1.12 g of acrylic acid were dissolved in 50 mL of tetrahydrofuran, and the resultant solution was subjected to nitrogen bubbling for 10 minutes. Subsequently, 0.018 g of dimethyl 2,2′-azobis(isobutyrate) serving as a polymerization initiator was added to the solution, and the resultant mixture was refluxed in a nitrogen atmosphere under heating at 70° C., to thereby perform polymerization for six hours. After the polymerization, the resultant solution was added to 1 L of n-hexane to precipitate a polymer, and the polymer was separated through filtration and then dried, to thereby yield a white polymer. The resultant polymer was found to have a benzyl acrylate structure (molar fraction: 80%) and an acrylic acid structure (molar fraction: 20%) by various analytical methods. The molecular weight of the polymer in terms of polystyrene was determined by gel permeation chromatography (GPC) in tetrahydrofuran. As a result, the polymer was found to have a weight average molecular weight (Mw) of 25,900.

<b. Preparation of Photosensitive Fiber-Producing Composition>

Firstly, 10 g of the aforementioned copolymer, 3 g of a dissolution inhibitor (naphthoquinone diazosulfonate ester compound), and 0.1 g of an electrolyte (tetrabutylammonium chloride) were dissolved in 40 g of an organic solvent (hexafluoroisopropanol), to thereby prepare a positive photosensitive fiber-producing composition. Subsequently, the solvent component was removed from the composition through drying. Thereafter, the glass transition temperature of the resultant solid component was determined with a differential scanning calorimeter (DSC). The glass transition temperature was 28.5° C.

<c. Production Method for Fiber by Electrospinning>

In this Example, the production of a fiber by electrospinning was performed with Esprayer ES-2000 (available from Fuence Co., Ltd.). The fiber-producing composition was injected into 1 mL of a lock-type glass syringe (available from AS ONE CORPORATION), and the syringe was attached to a lock-type metallic needle 24G having a needle length of 13 mm (available from Musashi Engineering, Inc.). The distance between the tip end of the needle and a substrate that receives a fiber (i.e., discharge distance) was 10 cm, the applied voltage was 5 kV, the discharge rate was 10 μL/min, and the discharge time was five seconds. The temperature in the interior of the laboratory was 23° C. during electrospinning.

<d. Patterning of Photosensitive Fiber>

An aluminum vapor-deposited PET film (the thickness of the PET film: 12 μm, the thickness of the aluminum vapor deposition film: 50 nm) was placed still, and the photosensitive fiber-producing composition was spun by electrospinning onto the surface of the aluminum vapor deposition film, to thereby form a fiber layer composed of entangled fiber filaments having a diameter of about 300 nm. In this case, the coating percentage (i.e., the percentage of the aluminum vapor-deposited PET film coated with the fiber of the fiber layer) was about 40%. Subsequently, heating was performed in an oven at 40° C. for five minutes, to thereby remove the solvent remaining in the fiber layer, and to adhere the fiber layer to the aluminum vapor-deposited PET film by utilizing the thermal melting of the fiber. Thereafter, an ultrahigh pressure mercury lamp was used as a light source, and the fiber layer was subjected to contact exposure via a photo mask having a circuit pattern including a wiring pattern (minimum line width: 50 μm). The exposure wavelength was adjusted to 350 nm to 450 nm (i.e., broad-band exposure), and the exposure dose was adjusted to 1,000 mJ/cm² as measured with i-ray wavelength. After the light exposure of the fiber layer, the resultant product was exposed to a developer (an aqueous alkaline solution containing a metal corrosion inhibitor (tetramethylammonium hydroxide: 0.0238%)) for two minutes, and then rinsed with pure water for five minutes. Thereafter, the resultant product was dried under heating in an oven at 40° C. for five minutes, to thereby form a fiber layer having a wiring pattern (line width: 50 μm) on the aluminum vapor-deposited PET film.

<e. Etching of Aluminum Vapor-Deposited PET Film>

The aluminum vapor-deposited PET film having thereon the above-formed fiber layer having a wiring pattern (line width: 50 μm) was immersed in an aluminum etchant Pure Etch AS1 (phosphoric acid-nitric acid-acetic acid system, available from Hayashi Pure Chemical Ind., Ltd.), and the aluminum was wet-etched with the fiber layer serving as an etching mask (25° C., five minutes). Thereafter, the fiber layer was thoroughly removed with an organic solvent (acetone), to thereby form, on the PET film, a circuit pattern including a wiring pattern (minimum line width: 50 μm) composed of a fine aluminum network structure (line width: about 300 nm).

<f. Electrical, Optical, and Mechanical Properties of Wiring Pattern>

The electrical property of the circuit pattern composed of the fine aluminum network structure (line width: about 300 nm) was measured by the four-terminal resistance measuring method. As a result, the circuit pattern was found to exhibit electrical conductivity, and exhibited a sheet resistance of about 10Ω/□. No anisotropy was observed in the electrical conductivity. Subsequently, the optical property of the circuit pattern was measured with an ultraviolet and visible spectrophotometer and was visually observed. As a result, the network metal pattern portion of the wiring pattern formed of the network metal pattern exhibited a light transmittance of about 60% at 380 nm to 780 nm (i.e., in a wavelength region of visible light), and was found to be transparent through visual observation. Subsequently, the circuit pattern was subjected to a bending test at a bend radius of 2 mm. The circuit pattern did not undergo a change in sheet resistance even after 100 times of bending, and maintained high electrical conductivity.

### Example 2

<a. Production of Copolymer>

Firstly, 10 g of 4-hydroxyphenyl methacrylate, 20.04 g of benzyl acrylate, and 7.92 g of benzyl methacrylate were dissolved in 120 mL of tetrahydrofuran, and the resultant solution was subjected to nitrogen bubbling for 10 minutes. Subsequently, 0.26 g of dimethyl 2,2′-azobis(isobutyrate) serving as a polymerization initiator was added to the solution, and the resultant mixture was refluxed in a nitrogen atmosphere under heating at 70° C., to thereby perform polymerization for six hours. After the polymerization, the resultant solution was added to 2 L of n-hexane to precipitate a polymer, and the polymer was separated through filtration and then dried, to thereby yield a white polymer. The resultant polymer was found to have a 4-hydroxyphenyl methacrylate structure (molar fraction: 25%), a benzyl acrylate structure (molar fraction: 55%), and a benzyl methacrylate structure (molar fraction: 20%) by various analytical methods. The molecular weight of the polymer in terms of polystyrene was determined by gel permeation chromatography (GPC) in tetrahydrofuran. As a result, the polymer was found to have a weight average molecular weight (Mw) of 31,000.

<b. Preparation of Photosensitive Fiber-Producing Composition>

Firstly, 10 g of the aforementioned copolymer, 3 g of a dissolution inhibitor (naphthoquinone diazosulfonate ester compound), and 0.5 g of an electrolyte (tetrabutylammonium chloride) were dissolved in 90 g of an organic solvent (hexafluoroisopropanol), to thereby prepare a positive photosensitive fiber-producing composition. Subsequently, the solvent component was removed from the composition through drying. Thereafter, the glass transition temperature of the resultant solid component was determined with a differential scanning calorimeter (DSC). The glass transition temperature was 85.6° C.

<c. Production Method for Fiber by Electrospinning>

In this Example, the production of a fiber by electrospinning was performed with Esprayer ES-2000 (available from Fuence Co., Ltd.). The fiber-producing composition was injected into 1 mL of a lock-type glass syringe (available from AS ONE CORPORATION), and the syringe was attached to a lock-type metallic needle 24G having a needle length of 13 mm (available from Musashi Engineering, Inc.). The distance between the tip end of the needle and a substrate that receives a fiber (i.e., discharge distance) was 20 cm, the applied voltage was 5 kV, the discharge rate was 10 μL/min, and the discharge time was five seconds. The temperature in the interior of the laboratory was 23° C. during electrospinning.

<d. Patterning of Photosensitive Fiber>

An aluminum vapor-deposited PET film (the thickness of the PET film: 12 μm, the thickness of the aluminum vapor deposition film: 50 nm) was placed still, and the photosensitive fiber-producing composition was spun by electrospinning onto the surface of the aluminum vapor deposition film, to thereby form a fiber layer composed of entangled fiber filaments having a diameter of about 500 nm. In this case, the coating percentage (i.e., the percentage of the aluminum vapor-deposited PET film coated with the fiber of the fiber layer) was about 20%. Subsequently, heating was performed in an oven at 90° C. for five minutes, to thereby remove the solvent remaining in the fiber layer, and to adhere the fiber layer to the aluminum vapor-deposited PET film by utilizing the thermal melting of the fiber. Thereafter, an ultrahigh pressure mercury lamp was used as a light source, and the fiber layer was subjected to contact exposure via a photo mask having a circuit pattern including a wiring pattern (minimum line width: 50 μm). The exposure wavelength was adjusted to 350 nm to 450 nm (i.e., broad-band exposure), and the exposure dose was adjusted to 280 mJ/cm² as measured with i-ray wavelength. After the light exposure of the fiber layer, the resultant product was exposed to a developer (an aqueous alkaline solution containing a metal corrosion inhibitor (tetramethylammonium hydroxide: 3.3%)) for two minutes, and then rinsed with pure water for five minutes. Thereafter, the resultant product was dried under heating in an oven at 40° C. for five minutes, to thereby form a fiber layer having a wiring pattern (line width: 50 μm) on the aluminum vapor-deposited PET film.

<e. Etching of Aluminum Vapor-Deposited PET Film>

The aluminum vapor-deposited PET film having thereon the above-formed fiber layer having a wiring pattern (line width: 50 μm) was immersed in an aluminum etchant Pure Etch AS1 (phosphoric acid-nitric acid-acetic acid system, available from Hayashi Pure Chemical Ind., Ltd.), and the aluminum was wet-etched with the fiber layer serving as an etching mask (25° C., one minute). Thereafter, the fiber layer was thoroughly removed with an organic solvent (acetone), to thereby form, on the PET film, a circuit pattern including a wiring pattern (minimum line width: 50 μm) composed of a fine aluminum network structure (line width: about 500 nm).

<f. Electrical, Optical, and Mechanical Properties of Wiring Pattern>

The electrical property of the circuit pattern composed of the fine aluminum network structure (line width: about 500 nm) was measured by the four-terminal resistance measuring method. As a result, the circuit pattern was found to exhibit electrical conductivity, and exhibited a sheet resistance of about 20Ω/□. No anisotropy was observed in the electrical conductivity. Subsequently, the optical property of the circuit pattern was measured with an ultraviolet and visible spectrophotometer and was visually observed. As a result, the network metal pattern portion of the wiring pattern formed of the network metal pattern exhibited a light transmittance of about 65% at 380 nm to 780 nm (i.e., in a wavelength region of visible light), and was found to be transparent through visual observation. Subsequently, the circuit pattern was subjected to a bending test at a bend radius of 2 mm. The circuit pattern did not undergo a change in sheet resistance even after 100 times of bending, and maintained high electrical conductivity.

### “Example 3” (in the Case of Low Percentage of the Aluminum Vapor-Deposited PET Film Coated with the Fiber of the Fiber Layer (Low Coating Percentage))

<a. Production Method for Fiber by Electrospinning>

In this Example, the production of a fiber by electrospinning was performed with Esprayer ES-2000 (available from Fuence Co., Ltd.). The fiber-producing composition was injected into 1 mL of a lock-type glass syringe (available from AS ONE CORPORATION), and the syringe was attached to a lock-type metallic needle 24G having a needle length of 13 mm (available from Musashi Engineering, Inc.). The distance between the tip end of the needle and a substrate that receives a fiber (i.e., discharge distance) was 20 cm, the applied voltage was 5 kV, the discharge rate was 10 μL/min, and the discharge time was one second. The temperature in the interior of the laboratory was 23° C. during electrospinning.

<b. Patterning of Photosensitive Fiber>

An aluminum vapor-deposited PET film (the thickness of the PET film: 12 μm, the thickness of the aluminum vapor deposition film: 50 nm) was placed still, and the photosensitive fiber-producing composition prepared in <b> of Example 2 was spun by electrospinning onto the surface of the aluminum vapor deposition film, to thereby form a fiber layer composed of entangled fiber filaments having a diameter of about 500 nm. In this case, the coating percentage (i.e., the percentage of the aluminum vapor-deposited PET film coated with the fiber of the fiber layer) was about 3%. Subsequently, heating was performed in an oven at 90° C. for five minutes, to thereby remove the solvent remaining in the fiber layer, and to adhere the fiber layer to the aluminum vapor-deposited PET film by utilizing the thermal melting of the fiber. Thereafter, an ultrahigh pressure mercury lamp was used as a light source, and the fiber layer was subjected to contact exposure via a photo mask having a circuit pattern including a wiring pattern (minimum line width: 50 μm). The exposure wavelength was adjusted to 350 nm to 450 nm (i.e., broad-band exposure), and the exposure dose was adjusted to 280 mJ/cm² as measured with i-ray wavelength. After the light exposure of the fiber layer, the resultant product was exposed to a developer (an aqueous alkaline solution containing a metal corrosion inhibitor (tetramethylammonium hydroxide: 3.3%)) for two minutes, and then rinsed with pure water for five minutes. Thereafter, the resultant product was dried under heating in an oven at 40° C. for five minutes, to thereby form a fiber layer having a wiring pattern (line width: 50 μm) on the aluminum vapor-deposited PET film.

<c. Etching of Aluminum Vapor-Deposited PET Film>

The aluminum vapor-deposited PET film having thereon the above-formed fiber layer having a wiring pattern (line width: 50 μm) was immersed in an aluminum etchant Pure Etch AS1 (phosphoric acid-nitric acid-acetic acid system, available from Hayashi Pure Chemical Ind., Ltd.), and the aluminum was wet-etched with the fiber layer serving as an etching mask (25° C., one minute). Thereafter, the fiber layer was thoroughly removed with an organic solvent (acetone), to thereby form, on the PET film, a circuit pattern including a wiring pattern (minimum line width: 50 μm) composed of a fine aluminum network structure (line width: about 500 nm).

<d. Electrical, Optical, and Mechanical Properties of Wiring Pattern>

The electrical property of the circuit pattern composed of the fine aluminum network structure (line width: about 500 nm) was measured by the four-terminal resistance measuring method. As a result, the circuit pattern was found to exhibit electrical conductivity, and exhibited a sheet resistance of about 250Ω/□. Subsequently, the optical property of the circuit pattern was measured with an ultraviolet and visible spectrophotometer and was visually observed. As a result, the network metal pattern portion of the wiring pattern formed of the network metal pattern exhibited a light transmittance of about 87% at 380 nm to 780 nm (i.e., in a wavelength region of visible light). Subsequently, the circuit pattern was subjected to a bending test at a bend radius of 2 mm. The circuit pattern did not undergo a change in sheet resistance even after 100 times of bending, and maintained high electrical conductivity.

### “Example 4” (in the Case of High Percentage of the Aluminum Vapor-Deposited PET Film Coated with the Fiber of the Fiber Layer (High Coating Percentage)) <a. Production Method for Fiber by Electrospinning>

In this Example, the production of a fiber by electrospinning was performed with Esprayer ES-2000 (available from Fuence Co., Ltd.). The fiber-producing composition was injected into 1 mL of a lock-type glass syringe (available from AS ONE CORPORATION), and the syringe was attached to a lock-type metallic needle 24G having a needle length of 13 mm (available from Musashi Engineering, Inc.). The distance between the tip end of the needle and a substrate that receives a fiber (i.e., discharge distance) was 20 cm, the applied voltage was 5 kV, the discharge rate was 10 μL/min, and the discharge time was 20 seconds. The temperature in the interior of the laboratory was 23° C. during electrospinning.

<b. Patterning of Photosensitive Fiber>

An aluminum vapor-deposited PET film (the thickness of the PET film: 12 μm, the thickness of the aluminum vapor deposition film: 50 nm) was placed still, and the photosensitive fiber-producing composition prepared in <b> of Example 2 was spun by electrospinning onto the surface of the aluminum vapor deposition film, to thereby form a fiber layer composed of entangled fiber filaments having a diameter of about 500 nm. In this case, the coating percentage (i.e., the percentage of the aluminum vapor-deposited PET film coated with the fiber of the fiber layer) was about 80%. Subsequently, heating was performed in an oven at 90° C. for five minutes, to thereby remove the solvent remaining in the fiber layer, and to adhere the fiber layer to the aluminum vapor-deposited PET film by utilizing the thermal melting of the fiber. Thereafter, an ultrahigh pressure mercury lamp was used as a light source, and the fiber layer was subjected to contact exposure via a photo mask having a circuit pattern including a wiring pattern (minimum line width: 50 μm). The exposure wavelength was adjusted to 350 nm to 450 nm (i.e., broad-band exposure), and the exposure dose was adjusted to 280 mJ/cm² as measured with i-ray wavelength. After the light exposure of the fiber layer, the resultant product was exposed to a developer (an aqueous alkaline solution containing a metal corrosion inhibitor (tetramethylammonium hydroxide: 3.3%)) for two minutes, and then rinsed with pure water for five minutes. Thereafter, the resultant product was dried under heating in an oven at 40° C. for five minutes, to thereby form a fiber layer having a wiring pattern (line width: 50 μm) on the aluminum vapor-deposited PET film.

<c. Etching of Aluminum Vapor-Deposited PET Film>

The aluminum vapor-deposited PET film having thereon the above-formed fiber layer having a wiring pattern (line width: 50 μm) was immersed in an aluminum etchant Pure Etch AS1 (phosphoric acid-nitric acid-acetic acid system, available from Hayashi Pure Chemical Ind., Ltd.), and the aluminum was wet-etched with the fiber layer serving as an etching mask (25° C., one minute). Thereafter, the fiber layer was thoroughly removed with an organic solvent (acetone), to thereby form, on the PET film, a circuit pattern including a wiring pattern (minimum line width: 50 μm) composed of a fine aluminum network structure (line width: about 500 nm).

<d. Electrical, Optical, and Mechanical Properties of Wiring Pattern>

The electrical property of the circuit pattern composed of the fine aluminum network structure (line width: about 500 nm) was measured by the four-terminal resistance measuring method. As a result, the circuit pattern was found to exhibit electrical conductivity, and exhibited a sheet resistance of about 8Ω/□. Subsequently, the optical property of the circuit pattern was measured with an ultraviolet and visible spectrophotometer and was visually observed. As a result, the network metal pattern portion of the wiring pattern formed of the network metal pattern exhibited a light transmittance of about 10% at 380 nm to 780 nm (i.e., in a wavelength region of visible light). Subsequently, the circuit pattern was subjected to a bending test at a bend radius of 2 mm. The circuit pattern did not undergo a change in sheet resistance even after 100 times of bending, and maintained high electrical conductivity.

### “Example 5” (in the Case of Large Fiber Diameter)

<a. Preparation of Photosensitive Fiber-Producing Composition>

Firstly, 10 g of the copolymer synthesized in <a> of Example 2, 3 g of a dissolution inhibitor (naphthoquinone diazosulfonate ester compound), and 0.5 g of an electrolyte (tetrabutylammonium chloride) were dissolved in 40 g of an organic solvent (hexafluoroisopropanol), to thereby prepare a positive photosensitive fiber-producing composition.

<b. Production Method for Fiber by Electrospinning>

In this Example, the production of a fiber by electrospinning was performed with Esprayer ES-2000 (available from Fuence Co., Ltd.). The fiber-producing composition was injected into 1 mL of a lock-type glass syringe (available from AS ONE CORPORATION), and the syringe was attached to a lock-type metallic needle 24G having a needle length of 13 mm (available from Musashi Engineering, Inc.). The distance between the tip end of the needle and a substrate that receives a fiber (i.e., discharge distance) was 20 cm, the applied voltage was 5 kV, the discharge rate was 10 μL/min, and the discharge time was five seconds. The temperature in the interior of the laboratory was 23° C. during electrospinning.

<c. Patterning of Photosensitive Fiber>

An aluminum vapor-deposited PET film (the thickness of the PET film: 12 μm, the thickness of the aluminum vapor deposition film: 50 nm) was placed still, and the photosensitive fiber-producing composition was spun by electrospinning onto the surface of the aluminum vapor deposition film, to thereby form a fiber layer composed of entangled fiber filaments having a diameter of about 2 μm. In this case, the coating percentage (i.e., the percentage of the aluminum vapor-deposited PET film coated with the fiber of the fiber layer) was about 20%. Subsequently, heating was performed in an oven at 90° C. for five minutes, to thereby remove the solvent remaining in the fiber layer, and to adhere the fiber layer to the aluminum vapor-deposited PET film by utilizing the thermal melting of the fiber. Thereafter, an ultrahigh pressure mercury lamp was used as a light source, and the fiber layer was subjected to contact exposure via a photo mask having a circuit pattern including a wiring pattern (minimum line width: 50 μm). The exposure wavelength was adjusted to 350 nm to 450 nm (i.e., broad-band exposure), and the exposure dose was adjusted to 280 mJ/cm² as measured with i-ray wavelength. After the light exposure of the fiber layer, the resultant product was exposed to a developer (an aqueous alkaline solution containing a metal corrosion inhibitor (tetramethylammonium hydroxide: 3.3%)) for two minutes, and then rinsed with pure water for five minutes. Thereafter, the resultant product was dried under heating in an oven at 40° C. for five minutes, to thereby form a fiber layer having a wiring pattern (line width: 50 μm) on the aluminum vapor-deposited PET film.

<d. Etching of Aluminum Vapor-Deposited PET Film>

The aluminum vapor-deposited PET film having thereon the above-formed fiber layer having a wiring pattern (line width: 50 μm) was immersed in an aluminum etchant Pure Etch AS1 (phosphoric acid-nitric acid-acetic acid system, available from Hayashi Pure Chemical Ind., Ltd.), and the aluminum was wet-etched with the fiber layer serving as an etching mask (25° C., one minute). Thereafter, the fiber layer was thoroughly removed with an organic solvent (acetone), to thereby form, on the PET film, a circuit pattern including a wiring pattern (minimum line width: 50 μm) composed of an aluminum network structure (line width: about 2 μm).

<e. Electrical, Optical, and Mechanical Properties of Wiring Pattern>

The electrical property of the circuit pattern composed of the aluminum network structure (line width: about 2 μm) was measured by the four-terminal resistance measuring method. As a result, the circuit pattern was found to exhibit electrical conductivity, and exhibited a sheet resistance of about 25Ω/□. Subsequently, the optical property of the circuit pattern was measured with an ultraviolet and visible spectrophotometer and was visually observed. As a result, the network metal pattern portion of the wiring pattern formed of the network metal pattern exhibited a light transmittance of about 60% at 380 nm to 780 nm (i.e., in a wavelength region of visible light), and was found to be transparent through visual observation. Subsequently, the circuit pattern was subjected to a bending test at a bend radius of 2 mm. The circuit pattern did not undergo a change in sheet resistance even after 100 times of bending, and maintained high electrical conductivity.

### “Comparative Example 1” (Bending Resistance of ITO Film)

<Electrical, Optical, and Mechanical Properties of ITO Transparent Electrically Conductive Film>

The electrical property of an ITO transparent electrically conductive film (ITO film thickness: about 75 nm) formed on a PET film was measured by the four-terminal resistance measuring method. As a result, the film exhibited a sheet resistance of about 100Ω/□. No anisotropy was observed in the electrical conductivity. Subsequently, the optical property of the film was measured with an ultraviolet and visible spectrophotometer and was visually observed. As a result, the film exhibited a light transmittance of about 78% at 550 nm (i.e., in a wavelength region of visible light), and was found to be transparent through visual observation. Subsequently, the film was subjected to a bending test at a bend radius of 2 mm. The sheet resistance of the film was increased to about 4 kΩ/□ after the bending was performed once, and the electrical conductivity of the film was considerably reduced.

1. A photosensitive fiber formed of a positive photosensitive material, wherein the positive photosensitive material comprises a (meth)acrylic resin or a polyvinyl phenol resin and a dissolution inhibitor.

2. A composition for producing a photosensitive fiber, the composition comprising a (meth)acrylic resin or a polyvinyl phenol resin, a dissolution inhibitor, and a solvent.

3. The composition according to claim 2, wherein the composition further comprises an electrolyte.

4. A method for producing a photosensitive fiber, the method comprising a step of spinning the composition according to claim 2.

5. A method for producing a photosensitive fiber pattern, the method comprising:
a first step of spinning the composition according to claim 2 to thereby form a fiber layer of photosensitive fiber on a substrate;
a second step of exposing the fiber layer to light via a mask; and
a third step of developing the fiber layer with a developer to thereby form a photosensitive fiber pattern.

6. A method for producing a metal pattern, the method comprising:
a first step of forming a fiber layer of photosensitive fiber on a substrate having on its surface a metal layer;
a second step of exposing the fiber layer to light via a mask;
a third step of developing the fiber layer with a developer to thereby form a photosensitive fiber pattern; and
a fourth step of etching the metal layer with an etchant and removing the photosensitive fiber, to thereby form a network metal pattern.

7. The method for producing a metal pattern according to claim 6, wherein the photosensitive fiber contains (i) a novolac resin and a dissolution inhibitor; or (ii) a polyvinyl phenol resin or a (meth)acrylic resin and a photoacid generator; or (iii) a polyvinyl phenol resin or a (meth)acrylic resin including a structural unit having a photoacid generating group on a side chain; or (iv) a polyvinyl phenol resin or a (meth)acrylic resin and a dissolution inhibitor.

8. The method for producing a metal pattern according to claim 6, wherein the network metal pattern exhibits a light transmittance of 5% or more in a wavelength region of visible light.

9. The method for producing a metal pattern according to claim 6, wherein the metal pattern can maintain electrical conductivity after 10 or more times of bending in a repeated bending test.

10. A method for producing a substrate having a metal pattern, the method comprising:
a first step of forming a fiber layer of photosensitive fiber on a substrate having on its surface a metal layer;
a second step of exposing the fiber layer to light via a mask;
a third step of developing the fiber layer with a developer to thereby form a photosensitive fiber pattern; and
a fourth step of etching the metal layer with an etchant and removing the photosensitive fiber, to thereby form a network metal pattern.

11. The method for producing a substrate having a metal pattern according to claim 10, wherein the photosensitive fiber contains (i) a novolac resin and a dissolution inhibitor; or (ii) a polyvinyl phenol resin or a (meth)acrylic resin and a photoacid generator; or (iii) a polyvinyl phenol resin or a (meth)acrylic resin including a structural unit having a photoacid generating group on a side chain; or (iv) a polyvinyl phenol resin or a (meth)acrylic resin and a dissolution inhibitor.

12. A substrate having a metal pattern produced by the method for producing a substrate having a metal pattern according to claim 10.

13. The substrate having a metal pattern according to claim 12, wherein the network metal pattern exhibits a light transmittance of 5% or more in a wavelength region of visible light.

14. The substrate having a metal pattern according to claim 12, wherein the substrate having a metal pattern can maintain electrical conductivity after ten or more times of bending in a repeated bending test.
